(19) United States
(12) Patent Application Publication
(10) Pub. No.: US 2025/0105235 A1
(43) Pub. Date: Mar. 27, 2025

(54) SEMICONDUCTOR PACKAGE

(71) Applicant: SAMSUNG ELECTRONICS CO., LTD., Suwon-si (KR)

(72) Inventor: JUNGHOON KANG, Suwon-si (KR)

(21) Appl. No.: 18/620,416

(22) Filed: Mar. 28, 2024

(30) Foreign Application Priority Data
Sep. 21, 2023 (KR) 10-2023-0126424

(51) Int. Cl. H01L 25/18; H01L 23/00; H01L 23/31; H01L 23/48; H01L 23/498; H01L 25/00; H01L 25/10

(52) U.S. Cl. CPC H01L 25/18; H01L 23/3128; H01L 23/481; H01L 23/49833; H01L 23/49838; H01L 24/08; H01L 24/16; H01L 24/32; H01L 24/73; H01L 25/105; H01L 25/50; H01L 23/49822; H01L 24/48; H01L 2224/08225; H01L 2224/16238; H01L 2224/32225; H01L 2224/48227; H01L 2224/73204; H01L 2224/73265; H01L 2225/1058; H01L 2924/1815

(57) ABSTRACT

A semiconductor package includes a first redistribution substrate, a first semiconductor chip having first pads on the first semiconductor chip, a second redistribution substrate on the first semiconductor chip, a first vertical connection structure through which the first and second redistribution substrates are electrically connected on one side of the first semiconductor chip, a second semiconductor chip on the second redistribution substrate, a first molding layer that covers the second semiconductor chip on the second redistribution substrate, a third redistribution substrate on the first molding layer; and a second vertical connection structure which is coupled to the second redistribution substrate and through which the second and third redistribution substrates are electrically connected on one side of the second semiconductor chip. A wiring pattern of the second redistribution substrate is coupled to the first pads of the first semiconductor chip.

### CROSS-REFERENCE TO RELATED APPLICATION

This U.S. nonprovisional application claims priority under 35 U.S.C § 119 to Korean Patent Application No. 10-2023-0126424 filed on Sep. 21, 2023 in the Korean Intellectual Property Office, the disclosure of which is hereby incorporated by reference in its entirety.

### BACKGROUND

The present inventive concepts relate to a semiconductor package and a method of fabricating the same, and more particularly, to a semiconductor package including a connection substrate and a method of fabricating the same.

A semiconductor package is provided to implement an integrated circuit chip to be suitable for use in electronic products. With recent developments in the electronic industry, semiconductor packages are being developed to reach the goal of compact size, small weight, and/or low manufacturing cost. A size of a semiconductor chip becomes smaller with high integration of the semiconductor chip. It may be difficult to adhere, handle, and test solder balls due to the small size of semiconductor chips. Additionally, there may be a problem of acquiring a diversified mount board due to the decreased size of semiconductor chips. Fan-out panel level packages may be utilized to address the above issues. However, in fan-out panel semiconductor packages, the area of redistribution lines is inevitably greater than that of the semiconductor chip. Accordingly, there may be a problem in that an excessively large area is given to the semiconductor chip compared to the utilization of the semiconductor chip.

### SUMMARY

Some embodiments of the present inventive concepts provide a semiconductor package with improved electrical properties and a method of fabricating the same.

Some embodiments of the present inventive concepts provide a semiconductor package with increased structural stability and a method of fabricating the same.

The object of the present inventive concepts is not limited to the mentioned above, and other objects which have not been mentioned above will be clearly understood to those skilled in the art from the following description.

According to some embodiments of the present inventive concepts, a semiconductor package may include: a first redistribution substrate; a first semiconductor chip on a top surface of the first redistribution substrate, wherein the first semiconductor chip includes a plurality of first pads on a top surface of the first semiconductor chip; a second redistribution substrate on the top surface of the first semiconductor chip; a first vertical connection structure adjacent one side of the first semiconductor chip, wherein the first redistribution substrate and the second redistribution substrate are electrically connected to each other by the first vertical connection structure; a second semiconductor chip on a top surface of the second redistribution substrate; a first molding layer on the second semiconductor chip; a third redistribution substrate on a top surface of the first molding layer; and a second vertical connection structure on the top surface of the second redistribution substrate and adjacent one side of the second semiconductor chip, wherein the second redistribution substrate and the third redistribution substrate are electrically connected to each other by the second vertical connection structure. A wiring pattern of the second redistribution substrate may be coupled to the plurality of first pads of the first semiconductor chip.

According to some embodiments of the present inventive concepts, a semiconductor package may comprise: a first redistribution substrate; a second redistribution substrate on the first redistribution substrate; a first connection substrate between the first redistribution substrate and the second redistribution substrate, wherein the first connection substrate includes a first opening in the first connection substrate and a plurality of pads on a top surface of the first connection substrate; a first semiconductor chip in the first opening between the first redistribution substrate and the second redistribution substrate, wherein the first semiconductor chip has a plurality of firth through vias that penetrate the first semiconductor chip; a first molding layer between the first redistribution substrate and the second redistribution substrate, wherein the first molding layer is on the first semiconductor chip and the first connection substrate and is in a space between the first semiconductor chip and the first connection substrate; a third redistribution substrate on the second redistribution substrate; a second connection substrate between the second redistribution substrate and the third redistribution substrate, wherein the second connection substrate includes a second opening in the second connection substrate and a plurality of second pads on a top surface of the second connection substrate; and a second semiconductor chip in the second opening between the second redistribution substrate and the third redistribution substrate. The second semiconductor chip and the second connection substrate are connected to a top surface of the second redistribution substrate by a plurality of first connection terminals between the second semiconductor chip and the second redistribution substrate and between the second connection substrate and the second redistribution substrate. A wiring pattern of the second redistribution substrate may penetrate the first molding layer and is coupled to the plurality of first pads.

According to some embodiments of the present inventive concepts, a semiconductor package may comprise: a lower package; and an upper package on the lower package. The lower package may include: a first redistribution substrate; a first connection substrate on a top surface of the first redistribution substrate, wherein the first connection substrate includes a first opening in the first connection substrate; a first semiconductor chip in the first opening and on the top surface of the first redistribution substrate, wherein the first semiconductor chip includes a plurality of first pads on a top surface of the first semiconductor chip; a plurality of external terminals on a bottom surface of the first redistribution substrate; a second redistribution substrate on the first connection substrate and the first semiconductor chip; a second connection substrate on a top surface of the second redistribution substrate, wherein the second connection substrate includes a second opening in the second connection substrate; a second semiconductor chip in the second opening and on the top surface of the second redistribution substrate; and a third redistribution substrate on the second redistribution substrate. The upper package may include: an upper package substrate; and an upper package chip on the upper package substrate. A wiring pattern of the second redistribution substrate may be coupled to the plurality of first pads of the first semiconductor chip.

### BRIEF DESCRIPTION OF DRAWINGS

FIG. 1 illustrates a cross-sectional view showing a semiconductor package according to some embodiments of the present inventive concepts.

FIGS. 2 and 3 illustrate enlarged views showing section A of FIG. 1.

FIGS. 4 to 9 illustrate cross-sectional views showing a semiconductor package according to some embodiments of the present inventive concepts.

FIGS. 10 to 15 illustrate cross-sectional views showing a method of fabricating a semiconductor package according to some embodiments of the present inventive concepts.

### DETAILED DESCRIPTION OF EMBODIMENTS

It will be hereinafter described a semiconductor package according to the present inventive concept with reference to accompanying drawings.

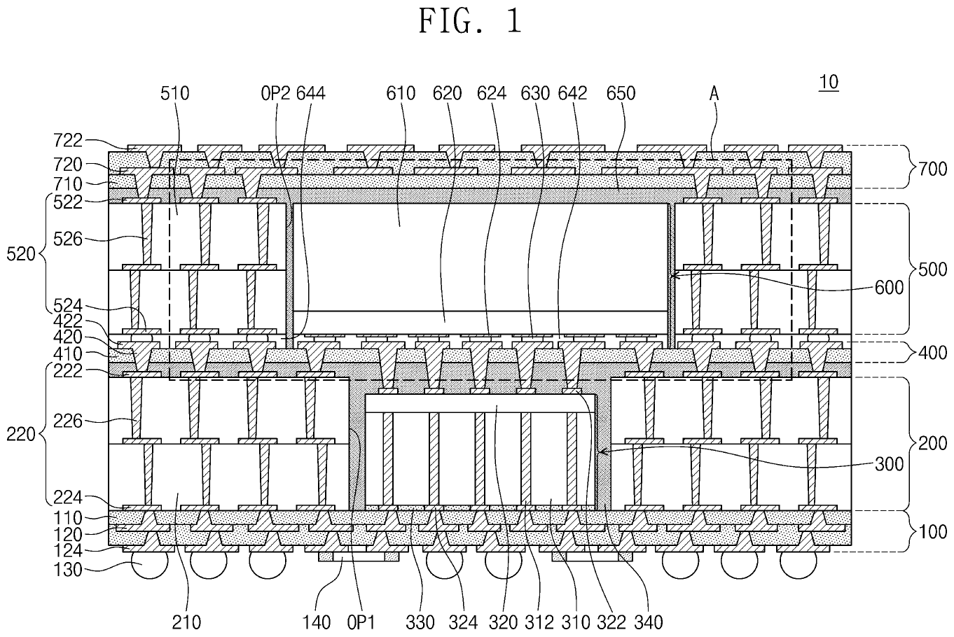

FIG. 1 illustrates a cross-sectional view showing a semiconductor package according to some embodiments of the present inventive concepts.

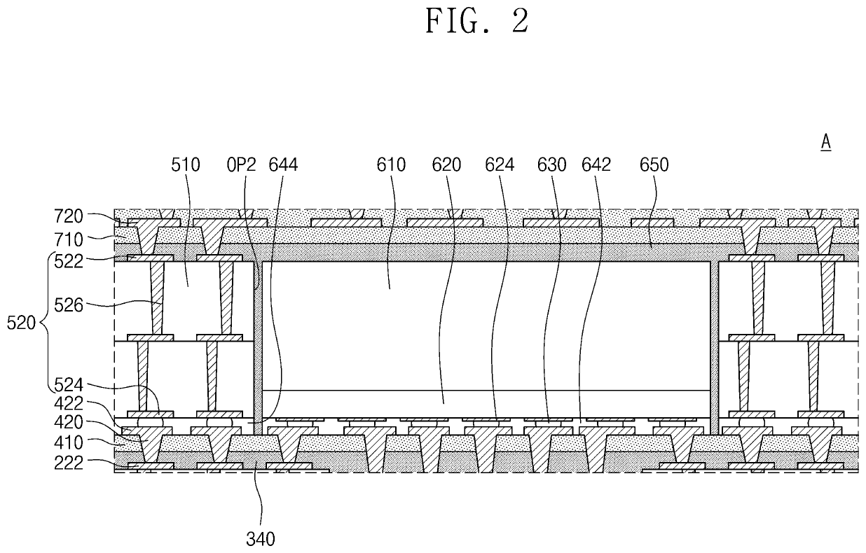

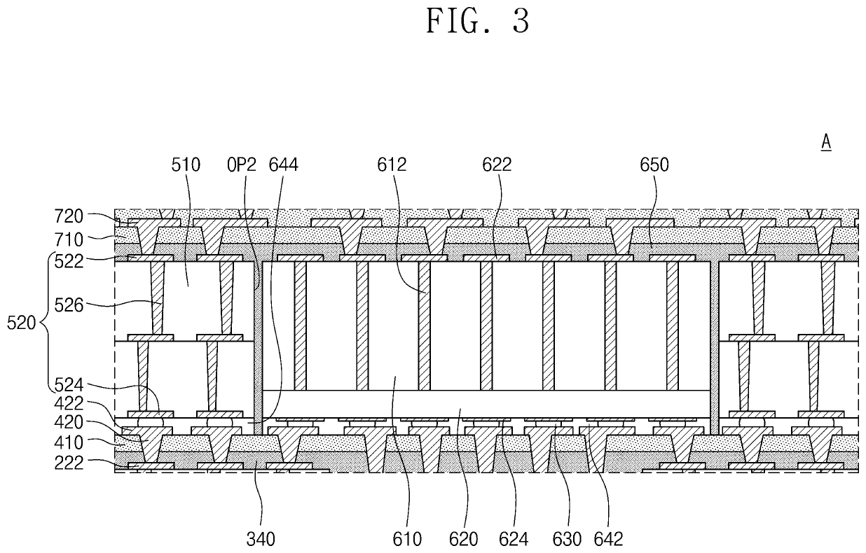

FIGS. 2 and 3 illustrate enlarged views of section A of FIG. 1, showing a semiconductor package according to some embodiments of the present inventive concepts.

Referring to FIGS. 1 and 2, a first redistribution substrate 100 may be provided. The first redistribution substrate 100 may include one first substrate wiring layer or at least two first substrate wiring layers that are stacked on each other. Each of the first substrate wiring layers may include a first substrate dielectric pattern 110 and a first substrate wiring pattern 120 in the first substrate dielectric pattern 110. The first substrate wiring pattern 120 of one first substrate wiring layer may be electrically connected to the first substrate wiring pattern 120 of an adjacent first substrate wiring layer. The following will describe an example in which one first substrate wiring layer is used to explain a configuration of the first substrate dielectric pattern 110 and the first substrate wiring pattern 120.

The first substrate dielectric pattern 110 may include a polymer. For example, the first substrate dielectric pattern 110 may include a dielectric polymer or a photo-imageable dielectric (PID). For example, the photo-imageable dielectric may include at least one selected from photosensitive polyimide, polybenzoxazole, phenolic polymers, and benzocyclobutene polymers. In some embodiments, the first substrate dielectric pattern 110 may include a dielectric material, such as silicon oxide (SiO), silicon nitride (SiN), or silicon oxynitride (SiON).

The first substrate wiring pattern 120 may be provided on a bottom surface of the first substrate dielectric pattern 110. The first substrate wiring pattern 120 may horizontally extend on the bottom surface of the first substrate dielectric pattern 110, as illustrated in FIG. 1. The first substrate wiring pattern 120 may protrude onto the bottom surface of the first substrate dielectric pattern 110, as illustrated in FIG. 1. Below the first substrate dielectric pattern 110, the first substrate wiring pattern 120 may be covered with an underlying first substrate dielectric pattern 110. The first substrate wiring pattern 120 provided in a lowermost first substrate wiring layer may be first pads 124 to which are coupled external terminals 130 and passive elements 140 which will be discussed below. As discussed above, the first substrate wiring pattern 120 may be a pad or line part of the first substrate wiring layer. For example, the first substrate wiring pattern 120 may be a component for horizontal redistribution in the first redistribution substrate 100. The first substrate wiring pattern 120 may include a conductive material, such as copper (Cu).

The first substrate wiring pattern 120 may have a damascene structure. For example, the first substrate wiring pattern 120 may have a via that protrudes onto a top surface thereof. The via may be a component for vertically connecting to each other the first substrate wiring patterns 120 of two neighboring ones of the first substrate wiring layers. For example, the via may extend from the top surface of the first substrate wiring pattern 120, and may penetrate the first substrate dielectric pattern 110 to be coupled to a bottom surface of the first substrate wiring pattern 120 of an overlying first substrate wiring layer. In some embodiments, the via may be a component for connecting the first substrate wiring pattern 120 of the uppermost first substrate wiring layer to a first connection substrate 200 or a first semiconductor chip 300 which will be discussed below. For example, the via may penetrate an uppermost first substrate dielectric pattern 110 to be coupled to a first connection substrate 200 or a first semiconductor chip 300 which will be discussed below. In this configuration, a lower portion of the first substrate wiring pattern 120 positioned on the bottom surface of the first substrate dielectric pattern 110 may be a head part used as a horizontal line or pad, and the via of the first substrate wiring pattern 120 may be a tail part. The first substrate wiring pattern 120 may have an inverse T shape, as illustrated in FIG. 1.

The first pads 124 may be provided with external terminals 130 on bottom surfaces thereof. The external terminals 130 may include a solder ball or a solder bump. Based on a type and arrangement of the external terminals 130, a semiconductor package may be provided in the shape of a ball grid array (BGA) or a land grid array (LGA).

The first pads 124 may be provided with passive elements 140 on the bottom surface thereof. The passive elements 140 may be disposed horizontally spaced apart from the external terminals 130. The passive elements 140 may serve to consume, accumulate, or discharge a power supplied through the first substrate wiring pattern 120. The passive elements 140 may correspond to ones of capacitors, inductors, and resistors. For example, the passive elements 140 may include a land side capacitor (LSC).

A first connection substrate 200 may be provided on the first redistribution substrate 100. The first connection substrate 200 may have a first opening OP1 that penetrates the first connection substrate 200. For example, the first opening OP1 may have an open hole shape that connects to each other top and bottom surfaces of the first connection substrate 200. The first opening OP1 may be defined to indicate a space in which is provided a first semiconductor chip 300 which will be discussed. The bottom surface of the first connection substrate 200 may be in contact with a top surface of the first redistribution substrate 100.

The first connection substrate 200 may include a first base layer 210 and a first conductive member 220 provided in the first base layer 210. The first connection substrate 200 may be a vertical connection structure that connects the first redistribution substrate 100 to a second redistribution substrate 400 which will be discussed below. The first conductive member 220 may be disposed between the first opening OP1 and an outer lateral surface of the first connection substrate 200. The first conductive member 220 may include first upper pads 222, first lower pads 224, and first vias 226.

The first upper pads 222 may be disposed on the top surface of the first connection substrate 200. The first upper pads 222 may protrude onto the top surface of the first connection substrate 200. In other embodiments, the first upper pads 222 may be buried in the first base layer 210, and top surfaces of the first upper pads 222 may be coplanar with the top surface of the first connection substrate 200. The first lower pads 224 may be disposed on the bottom surface of the first connection substrate 200. The first lower pads 224 may be buried in the first base layer 210, and bottom surfaces of the first lower pads 224 may be coplanar with the bottom surface of the first connection substrate 200. The first vias 226 may penetrate the first base layer 210 to electrically connect the first upper pads 222 to the first lower pads 224. The first base layer 210 may include a polymer. For example, the first base layer 210 may include a dielectric polymer or a photo-imageable dielectric (PID). For example, the photo-imageable dielectric may include at least one selected from photosensitive polyimide, polybenzoxazole, phenolic polymers, and benzocyclobutene polymers. In some embodiments, the first base layer 210 may include a dielectric material. The first base layer 210 may include, for example, silicon oxide (SiO), silicon nitride (SiN), or silicon oxynitride (SiON). In some embodiments, the first base layer 210 may include a prepreg. The first upper pads 222, the first lower pads 224, and the first vias 226 may include a conductor or metal such as copper (Cu).

FIG. 1 depicts that the first base layer 210 is separated into two layers, but the present inventive concepts are not limited thereto. The first base layer 210 may be separated into three or four layers.

The first connection substrate 200 may be mounted on the first redistribution substrate 100. For example, the first connection substrate 200 may be in contact with the first redistribution substrate 100. The first substrate wiring pattern 120 of the uppermost first substrate wiring layer may penetrate the first substrate dielectric pattern 110 to be coupled to the first lower pads 224.

A first semiconductor chip 300 may be disposed on the first redistribution substrate 100. The first semiconductor chip 300 may be disposed in the first opening OP1 of the first connection substrate 200. In this case, the first semiconductor chip 300 may be placed on the first redistribution substrate 100 exposed by the first opening OP1. The first semiconductor chip 300 may be in contact with the top surface of the first redistribution substrate 100. The first semiconductor chip 300 may be spaced apart from the first connection substrate 200. For example, the first semiconductor chip 300 may be spaced apart from an inner sidewall of the first opening OP1, as illustrated in FIG. 1. A top surface of the first semiconductor chip 300 may be located at a level from the first redistribution substrate 100 lower than a level of the top surface of the first connection substrate 200. In some embodiments, the top surface of the first semiconductor chip 300 may be located at a level from the first redistribution substrate 100 the same as the level of the top surface of the first connection substrate 200 (i.e., the top surface of the first semiconductor chip 300 may be co-planar with the top surface of the first connection substrate 200).

The first semiconductor chip 300 may be a logic chip. In some embodiments, the first semiconductor chip 300 may be a memory chip, such as DRAM, SRAM, MRAM, or Flash memory. The first semiconductor chip 300 may have a front surface and a rear surface. In this description, the term “front surface” may be defined to indicate a surface on an active surface side of an integrated element in a semiconductor chip, and the term “rear surface” may be defined to indicate a surface opposite to the front surface. The first semiconductor chip 300 may be face-up disposed on the first redistribution substrate 100. For example, the rear surface of the first semiconductor chip 300 may face the first redistribution substrate 100. For example, a bottom surface of the first semiconductor chip 300 may be the rear surface of the first semiconductor chip 300, and the top surface of the first semiconductor chip 300 may be the front surface of the first semiconductor chip 300. The first semiconductor chip 300 may include a first semiconductor substrate 310, a first circuit layer 320 provided on the top surface of the first semiconductor substrate 310, and first through vias 312 that vertically penetrate the first semiconductor substrate 310.

The first semiconductor substrate 310 may be a semiconductor substrate. For example, the first semiconductor substrate 310 may include silicon (Si). An integrated element or integrated circuits may be formed on a top surface of the first semiconductor substrate 310.

The first circuit layer 320 may be provided on the top surface of the first semiconductor substrate 310. A wiring pattern in the first circuit layer 320 may be electrically connected to the integrated element or the integrated circuits formed on the top surface of the first semiconductor substrate 310.

The first circuit layer 320 may be provided with first chip pads 322 on a top surface thereof. The first chip pads 322 may be electrically connected through the first circuit layer 320 to the integrated element or the integrated circuits. The first chip pads 322 may include a conductive material. For example, the first chip pads 322 may include metal, such as copper (Cu).

The first semiconductor chip 300 may be provided with second chip pads 324 on the bottom surface thereof. The second chip pads 324 may include a conductive material, such as copper (Cu).

The first through vias 312 may vertically penetrate the first semiconductor substrate 310. The first through vias 312 may extend toward the top surface of the first semiconductor chip 300 to come into connection either with the first circuit layer 320 or with the integrated element or the integrated circuits formed on the first semiconductor substrate 310. The first through vias 312 may extend toward the bottom surface of the first semiconductor chip 300 to come into connection with the second chip pads 324.

The first semiconductor substrate 310 may be provided on its bottom surface with a dielectric layer 330 that surrounds (e.g., extends around) the second chip pads 324. The dielectric layer 330 may cover the bottom surface of the first semiconductor substrate 310 and may expose bottom surfaces of the second chip pads 324. The dielectric layer 330 may include a dielectric material, such as silicon oxide (SiO), silicon nitride (SiN), or silicon oxynitride (SiON).

A first semiconductor chip 300 may be mounted on the first redistribution substrate 100. For example, the first semiconductor chip 300 may be in contact with the first redistribution substrate 100. The first substrate wiring pattern 120 of the uppermost first substrate wiring layer may penetrate the first substrate dielectric pattern 110 to be coupled to the second chip pads 324. The first substrate wiring pattern 120 may be connected through the second chip pads 324 to the first through vias 312. In other embodiments, neither the second chip pads 324 nor the dielectric layer 330 may be provided. In this case, the first substrate wiring pattern 120 may be directly coupled to the first through vias 312. The first semiconductor chip 300 may be electrically connected through the first substrate wiring pattern 120 to the first connection substrate 200.

A first molding layer 340 may be provided on the first redistribution substrate 100. On the first redistribution substrate 100, the first molding layer 340 may cover the first connection substrate 200 and the first semiconductor chip 300. The first molding layer 340 may cover the top surface of the first connection substrate 200 and the top surface of the first semiconductor chip 300. In the first opening OP1 of the first connection substrate 200, the first molding layer 340 may fill a space between the first connection substrate 200 and the first semiconductor chip 300. The first molding layer 340 may include a dielectric polymer material. For example, the first molding layer 340 may include an epoxy molding compound (EMC). In some embodiments, the first molding layer 340 may include an epoxy dielectric film. For example, the first molding layer 340 may include an Ajinomoto build-up film (ABF).

A second redistribution substrate 400 may be provided on the first molding layer 340. The second redistribution substrate 400 may include one second substrate wiring layer. The second substrate wiring layer may include a second substrate dielectric pattern 410 and a second substrate wiring pattern 420 in the second substrate dielectric pattern 410.

The second substrate dielectric pattern 410 may include a dielectric polymer or a photo-imageable dielectric (PID). For example, the photo-imageable dielectric may include at least one selected from photosensitive polyimide, polybenzoxazole, phenolic polymers, and benzocyclobutene polymers. The second substrate dielectric pattern 410 may include a dielectric material. For example, the second substrate dielectric pattern 410 may include silicon oxide (SiO), silicon nitride (SiN), or silicon oxynitride (SiON).

The second substrate wiring pattern 420 may be provided on a top surface of the second substrate dielectric pattern 410. The second substrate wiring pattern 420 may horizontally extend on the top surface of the second substrate dielectric pattern 410, as illustrated in FIG. 1. The second substrate wiring pattern 420 may protrude onto the top surface of the second substrate dielectric pattern 410, as illustrated in FIG. 1. The second substrate wiring pattern 420 may be second pads 422 to which first connection terminals 630 are coupled which will be discussed below. The second substrate wiring pattern 420 may be a pad or line part of the second substrate wiring layer. For example, the second substrate wiring pattern 420 may be a component for horizontal redistribution in the second redistribution substrate 400. The second substrate wiring pattern 420 may include a conductive material, such as copper (Cu).

The second substrate wiring pattern 420 may have a damascene structure. For example, the second substrate wiring pattern 420 may have a via that protrudes onto a bottom surface thereof. The via may be a component for connecting the second substrate wiring pattern 420 to the first semiconductor chip 300 or the first connection substrate 200. For example, the via may penetrate the second substrate dielectric pattern 410 and the first molding layer 340 to be coupled to the first upper pads 222 or the first chip pads 322. The first connection substrate 200 and the first semiconductor chip 300 may be electrically connected through the second substrate wiring pattern 420. In this configuration, an upper portion of the second substrate wiring pattern 420 positioned on the top surface of the second substrate dielectric pattern 410 may be a head part used as a horizontal line or pad, and the via of the second substrate wiring pattern 420 may be a tail part. The second substrate wiring pattern 420 may have a T shape, as illustrated in FIG. 1.

FIG. 1 depicts that the second redistribution substrate 400 includes one second substrate wiring layer, but the present inventive concepts are not limited thereto. The second redistribution substrate 400 may include at least two second substrate wiring layers that are stacked on each other. In this case, the second pads 422 may be the second substrate wiring pattern 420 provided on an uppermost second substrate wiring layer. In addition, the via connected to the first semiconductor chip 300 or the first connection substrate 200 may be the second substrate wiring pattern 420 provided in a lowermost second substrate wiring layer.

A second connection substrate 500 may be provided on the second redistribution substrate 400. The second connection substrate 500 may be substantially similar to the first connection substrate 200 discussed above. The second connection substrate 500 may have a second opening OP2 that penetrates the second connection substrate 500. For example, the second opening OP2 may have an open hole shape that connects to each other top and bottom surfaces of the second connection substrate 500. The second opening OP2 may be defined to indicate a space in which is provided a second semiconductor chip 600 which will be discussed. The bottom surface of the second connection substrate 500 may be in contact with a top surface of the second redistribution substrate 400.

The second connection substrate 500 may include a second base layer 510 and a second conductive member 520 provided in the second base layer 510. The second connection substrate 500 may be a vertical connection structure that connects the second redistribution substrate 400 to a third redistribution substrate 700 which will be discussed below. The second conductive member 520 may be disposed between the second opening OP2 and an outer lateral surface of the second connection substrate 500. The second conductive member 520 may include second upper pads 522, second lower pads 524, and second vias 526.

The second upper pads 522 may be disposed on the top surface of the second connection substrate 500. The second upper pads 522 may protrude onto the top surface of the second connection substrate 500. In other embodiments, the second upper pads 522 may be buried in an uppermost second base layer 510, and top surfaces of the second upper pads 522 in the uppermost second base layer 510 may be coplanar with the top surface of the second connection substrate 500. The second lower pads 524 may be disposed on the bottom surface of the second connection substrate 500. The second lower pads 524 may be buried in a lowermost second base layer 510, and bottom surfaces of the second lower pads 524 may be coplanar with the bottom surface of the second connection substrate 500. The second vias 526 may penetrate the second base layer 510 to electrically connect the second upper pads 522 to the second lower pads 524.

FIG. 1 depicts that the second base layer 510 is separated into two layers, but the present inventive concepts are not limited thereto. The second base layer 510 may be separated into three or four layers.

A second semiconductor chip 600 may be provided on the second redistribution substrate 400. The second semiconductor chip 600 may be disposed in the second opening OP2 of the second connection substrate 500. In this case, the second semiconductor chip 600 may be disposed on the second redistribution substrate 400 exposed by the second opening OP2. The second semiconductor chip 600 may be in contact with the top surface of the second redistribution substrate 400. The second semiconductor chip 600 may be spaced apart from the second connection substrate 500. For example, the second semiconductor chip 600 may be spaced apart from an inner sidewall of the second opening OP2, as illustrated in FIG. 1. A top surface of the second semiconductor chip 600 may be located at a level from the second redistribution substrate 400 the same as a level of the top surface of the second connection substrate 500 (i.e., the top surface of the second semiconductor chip 600 may be co-planar with the top surface of the second connection substrate 500). In some embodiments, the top surface of the second semiconductor chip 600 may be located at a level from the second redistribution substrate 400 higher or lower than the level of the top surface of the second connection substrate 500.

The second semiconductor chip 600 may be a logic chip. In other embodiments, the second semiconductor chip 600 may be a memory chip, such as DRAM, SRAM, MRAM, or Flash memory. The second semiconductor chip 600 may have a width greater than that of the first semiconductor chip 300. The second semiconductor chip 600 may be face-down disposed on the second redistribution substrate 400. For example, a front surface of the second semiconductor chip 600 may be directed toward the second redistribution substrate 400. A bottom surface of the second semiconductor chip 600 may be the front surface of the second semiconductor chip 600, and the top surface of the second semiconductor chip 600 may be a rear surface of the second semiconductor chip 600. The second semiconductor chip 600 may include a second semiconductor substrate 610 and a second circuit layer 620 provided on a bottom surface of the second semiconductor substrate 610.

The second semiconductor substrate 610 may be a semiconductor substrate. For example, the second semiconductor substrate 610 may include silicon (Si). The second semiconductor substrate 610 may be provided with an integrated element or integrated circuits on a top surface thereof.

The second circuit layer 620 may be provided on the bottom surface of the second semiconductor substrate 610. A wiring pattern in the second circuit layer 620 may be electrically connected to the integrated element or the integrated circuits formed on the bottom surface of the second semiconductor substrate 610.

The second circuit layer 620 may be provided with third chip pads 624 on the bottom surface thereof. The third chip pads 624 may be electrically connected through the second circuit layer 620 to the integrated element or the integrated circuits. The third chip pads 624 may include a conductive material. For example, the third chip pads 624 may include metal such as copper (Cu).

According to some embodiments, the second semiconductor chip 600 may further include second through vias 612 (FIG. 3) that penetrate the second semiconductor substrate 610. As illustrated in FIG. 3, the second through vias 612 may extend toward the bottom surface of the second semiconductor chip 600 to come into connection with the second circuit layer 620. The second through vias 612 may extend toward the top surface of the second semiconductor chip 600 to come into connection with fourth chip pads 622. The fourth chip pads 622 may be provided on the top surface of the second semiconductor chip 600. The fourth chip pads 622 may include a conductive material, such as copper (Cu). The following description will be disclosed continuously with reference to FIGS. 1 and 2.

The second connection substrate 500 and the second semiconductor chip 600 may be mounted on the second redistribution substrate 400. For example, the second connection substrate 500 and the second semiconductor chip 600 may be coupled through the first connection terminals 630 to the second pads 422. The first connection terminals 630 may be provided between the second pads 422 and the third chip pads 624 and between the second pads 422 and the second lower pads 524. For example, the second connection substrate 500 and the second semiconductor chip 600 may be electrically connected to the second redistribution substrate 400 through the first connection terminals 630 and the second substrate wiring pattern 420. The second connection substrate 500 and the second semiconductor chip 600 may have their bottom surfaces spaced apart from the second redistribution substrate 400. The first connection terminals 630 may include a solder ball or a solder bump.

According to some embodiments of the present inventive concepts, the second connection substrate 500 and the second semiconductor chip 600 may be mounted on the top surface of the second redistribution substrate 400 directly coupled to the first connection substrate 200 and the first semiconductor chip 300. No discrete redistribution substrate may be provided to connect the second connection substrate 500 to the second semiconductor chip 600. In addition, no solder balls may be separately provided to connect the discrete redistribution substrate to the second redistribution substrate 400. Therefore, a semiconductor package may be provided which has a small size and improved structural stability.

In addition, the first and second connection substrate 200 and 500 and the first and second semiconductor chips 300 and 600 may be connected to each other through the second substrate wiring pattern 420, and thus there may be a reduction in electrical length. Accordingly, a semiconductor package may have improved electrical properties.

A first underfill layer 642 may be provided between the top surface of the second redistribution substrate 400 and the bottom surface of the second semiconductor chip 600. The first underfill layer 642 may fill a space between the second redistribution substrate 400 and the second semiconductor chip 600, and may surround the third chip pads 624, the first connection terminals 630, and the second pads 422.

A second underfill layer 644 may be provided between the top surface of the second redistribution substrate 400 and the bottom surface of the second connection substrate 500. The second underfill layer 644 may fill a space between the second redistribution substrate 400 and the second connection substrate 500, and may surround the second lower pads 524, the first connection terminals 630, and the second pads 422. In other embodiments, the first underfill layer 642 and the second underfill layer 644 may be connected into a single component (i.e., the first underfill layer 642 and the second underfill layer 644 may be a single underfill layer). In other embodiments, no underfill layer may be provided between the second redistribution substrate 400 and each of the second connection substrate 500 and the second semiconductor chip 600. In this case, a second molding layer 650, which will be discussed below, may fill a space between the second redistribution substrate 400 and the second connection substrate 500 and between the second redistribution substrate 400 and the second semiconductor chip 600.

A second molding layer 650 may be provided on the second redistribution substrate 400. On the second redistribution substrate 400, the second molding layer 650 may cover the second connection substrate 500 and the second semiconductor chip 600. The second molding layer 650 may fill a space between the second connection substrate 500 and the second semiconductor chip 600 and a space between the first underfill layer 642 and the second underfill layer 644. The second molding layer 650 may include a dielectric polymer material. For example, the second molding layer 650 may include an epoxy molding compound (EMC) or an epoxy dielectric film such as an Ajinomoto build-up film (ABF).

A third redistribution substrate 700 may be provided on the second molding layer 650. The third redistribution substrate 700 may be substantially similar to the second redistribution substrate 400 discussed above. The third redistribution substrate 700 may include one third substrate wiring layer or at least two third substrate wiring layers that are stacked on each other. Each of the third substrate wiring layers may include a third substrate dielectric pattern 710 and a third substrate wiring pattern 720 in the third substrate dielectric pattern 710. The third substrate wiring pattern 720 provided on an uppermost third substrate wiring layer may be third pads 722 to which is coupled an external apparatus mounted on the third redistribution substrate 700.

The third substrate wiring pattern 720 may have a damascene structure. For example, the third substrate wiring pattern 720 may have a via that protrudes onto a bottom surface thereof. The via may be a component for vertically connecting to each other the third substrate wiring patterns 720 of two neighboring ones of the third substrate wiring layers. The via may be a component for connecting the third substrate wiring pattern 720 of a lowermost third substrate wiring layer to the second connection substrate 500. For example, the via may penetrate a lowermost third substrate dielectric pattern 710 and the second molding layer 650 to be coupled to the second upper pads 522 of the second connection substrate 500. According to some embodiments, as illustrated in FIG. 3, the via may penetrate the lowermost third substrate dielectric pattern 710 and the second molding layer 650 to be coupled to the second upper pad 522 and the fourth chip pad 622 of the second semiconductor chip 600. Therefore, the via may be connected through the fourth chip pads 622 to the second through vias 612. In other embodiments, the fourth chip pads 622 may not be provided. In this case, the via may be directly connected to the second through vias 612 of the second semiconductor chip 600. The following description will be disclosed with reference to FIGS. 1 and 2. In this configuration, a upper portion of the third substrate wiring pattern 720 positioned on a top surface of the third substrate dielectric pattern 710 may be a head part used as a horizontal line or pad, and the via of the third substrate wiring pattern 720 may be a tail part. The third substrate wiring pattern 720 may have a T shape, as illustrated in FIG. 1.

There may be provided a semiconductor package 10 as discussed above. According to some embodiments of the present inventive concepts, the first semiconductor chip 300 may be provided therein with the first through vias 312 that penetrate the first semiconductor chip 300. The first redistribution substrate 100 may be connected through the first through vias 312 to the second redistribution substrate 400. Therefore, a reduced electrical connection length may be provided between the first redistribution substrate 100 and the second redistribution substrate 400. In addition, the second semiconductor chip 600 may be provided therein with the second through vias 612 that penetrate the second semiconductor chip 600. The second redistribution substrate 400 may be connected through the second through vias 612 to the third redistribution substrate 700. Therefore, a reduced electrical connection length may be provided between the second redistribution substrate 400 and the third redistribution substrate 700. Accordingly, the semiconductor package may have improved electrical properties.

In the embodiments that follow, a detailed description of technical features repetitive to those discussed above with reference to FIG. 1 will be omitted, and a difference thereof will be discussed in detail. The same reference numerals may be allocated to the same components of the semiconductor package 10 discussed above according to some embodiments of the present inventive concepts.

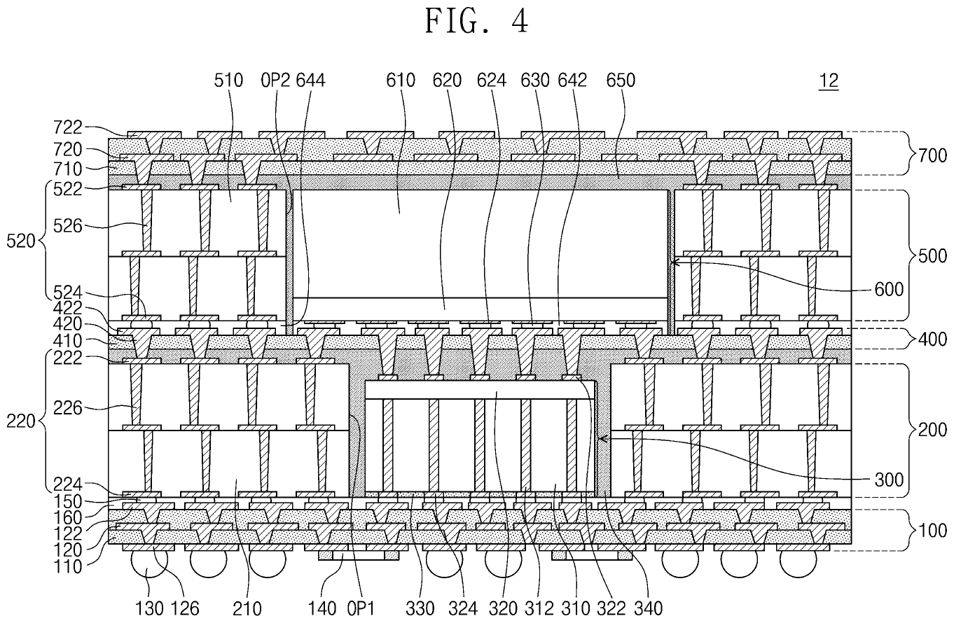

FIG. 4 illustrates a cross-sectional view showing a semiconductor package according to some embodiments of the present inventive concepts.

Referring to FIG. 4, a semiconductor package 12 may be provided. The semiconductor package 12 may be substantially similar to the semiconductor package 10 discussed above with reference to FIG. 1.

The first redistribution substrate 100 may be provided in a lower portion of the semiconductor package 12. The first redistribution substrate 100 may include one first substrate wiring layer or at least two first substrate wiring layers. The first substrate wiring layers may include the first substrate dielectric pattern 110 and the first substrate wiring pattern 120 in the first substrate dielectric pattern 110. The first substrate wiring pattern 120 of one first substrate wiring layer may be electrically connected to the first substrate wiring pattern 120 of an adjacent first substrate wiring layer. The following will describe an example in which one first substrate wiring layer is used to explain a configuration of the first substrate dielectric pattern 110 and the first substrate wiring pattern 120.

The first substrate wiring pattern 120 may be provided on a top surface of the first substrate dielectric pattern 110. The first substrate wiring pattern 120 may horizontally extend on the top surface of the first substrate dielectric pattern 110. The first substrate wiring pattern 120 may protrude onto the top surface of the first substrate dielectric pattern 110, as illustrated in FIG. 4. The first substrate wiring pattern 120 may be covered with another first substrate dielectric pattern 110 that overlies the first substrate dielectric pattern 110. The first substrate wiring pattern 120 may be fourth pads 122 to which second connection terminals 150 are coupled which will be discussed below. As discussed above, the first substrate wiring pattern 120 may be a pad or line part of the first substrate wiring layer. For example, the first substrate wiring pattern 120 may be a component for horizontal redistribution in the first redistribution substrate 100.

The first substrate wiring pattern 120 may have a damascene structure. For example, the first substrate wiring pattern 120 may have a via that protrudes onto a bottom surface thereof. The via may penetrate the first substrate dielectric pattern 110 to be coupled to fifth pads 126 disposed on a bottom surface of the first redistribution substrate 100. In this configuration, an upper portion of the first substrate wiring pattern 120 positioned on the top surface of the first substrate dielectric pattern 110 may be a head part used as a horizontal line or pad, and the via of the first substrate wiring pattern 120 may be a tail part. The first substrate wiring pattern 120 may have a T shape, as illustrated in FIG. 4.

The first connection substrate 200 and the first semiconductor chip 300 may be mounted on the first redistribution substrate 100. Second connection terminals 150 may be interposed between the fourth pads 122 and the first lower pads 224 and between the fourth pads 122 and the second chip pads 324. The first redistribution substrate 100 may be electrically connected through the second connection terminals 150 to the first connection substrate 200 and the first semiconductor chip 300. The second connection terminals 150 may include a solder ball or a solder bump.

A third underfill layer 160 may be interposed between a top surface of the first redistribution substrate 100 and each of a bottom surface of the first connection substrate 200 and a bottom surface of the first semiconductor chip 300. The third underfill layer 160 may fill a space between the first redistribution substrate 100 and the first connection substrate 200 and a space between the first redistribution substrate 100 and the first semiconductor chip 300. The third underfill layer 160 may cover the second connection terminals 150, the fourth pads 122, and the second chip pads 324.

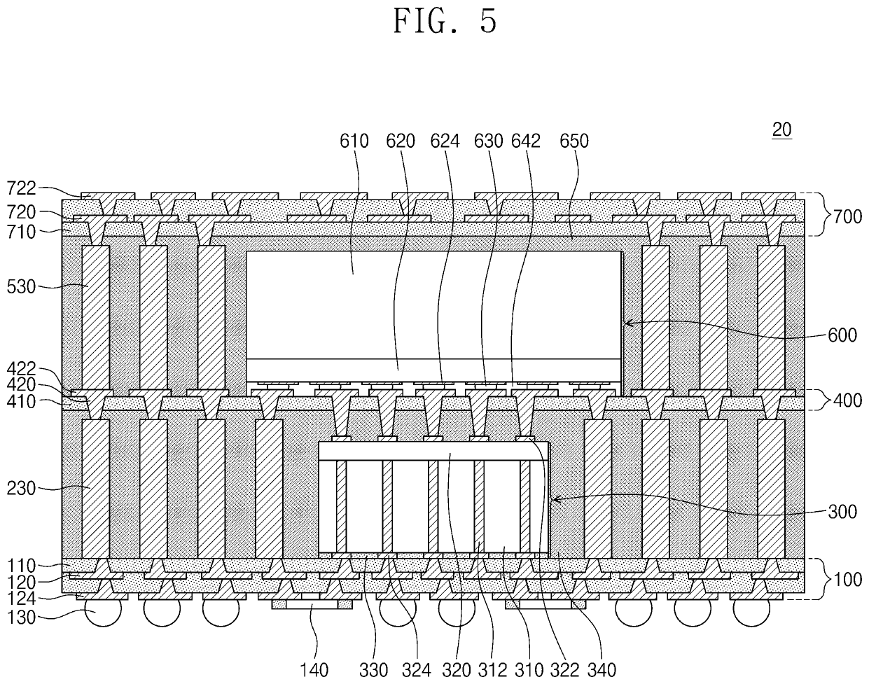

FIGS. 5 to 7 illustrate cross-sectional views showing a semiconductor package according to some embodiments of the present inventive concepts.

Referring to FIG. 5, a semiconductor package 20 may be provided.

The first redistribution substrate 100 may be provided thereon with a first semiconductor chip 300, first conductive posts 230, and a first molding layer 340. The first semiconductor chip 300 may be substantially the same as or similar to the first semiconductor chip 300 discussed above with reference to FIG. 1. The first semiconductor chip 300 may be disposed on a central region of the first redistribution substrate 100. On a top surface of the first redistribution substrate 100, the first semiconductor chip 300 may be spaced apart from the first conductive posts 230 in a direction parallel to the top surface of the first redistribution substrate 100. The first molding layer 340 may cover the first semiconductor chip 300 and may surround the first conductive posts 230.

The first conductive posts 230 may be disposed on one side of the first semiconductor chip 300. The first conductive posts 230 may be disposed between an outer lateral surface of the first semiconductor chip 300 and an outer lateral surface of the first molding layer 340. The first conductive posts 230 may vertically penetrate the first molding layer 340. The first conductive posts 230 may have their ends that extend toward the top surface of the first redistribution substrate 100. The first conductive posts 230 may have their bottom surfaces exposed on a bottom surface of the first molding layer 340. The bottom surfaces of the first conductive posts 230 may be coplanar with the bottom surface of the first molding layer 340. The first conductive posts 230 may penetrate the first molding layer 340 to be coupled to the first substrate wiring pattern 120. The first conductive posts 230 may have their other ends that extend toward a bottom surface of the second redistribution substrate 400. The first conductive posts 230 may have their top surfaces exposed on a top surface of the first molding layer 340. The top surfaces of the first conductive posts 230 may be coplanar with the top surface of the first molding layer 340. The first conductive posts 230 may penetrate the first molding layer 340 to be coupled to the second substrate wiring pattern 420. For example, the first redistribution substrate 100 may be connected through the first conductive posts 230 to the second redistribution substrate 400. The first conductive posts 230 may be a vertical connection structure that connects the first redistribution substrate 100 to the second redistribution substrate 400. The first conductive posts 230 may include a conductive material, such as copper (Cu).

The second redistribution substrate 400 may be provided thereon with a second semiconductor chip 600, second conductive posts 530, and a second molding layer 650. The second semiconductor chip 600 may be substantially the same as or similar to the second semiconductor chip 600 discussed above with reference to FIG. 1. The second semiconductor chip 600 may be disposed on a central region of the second redistribution substrate 400. On a top surface of the second redistribution substrate 400, the second semiconductor chip 600 may be spaced apart from the second conductive posts 530 in a direction parallel to the top surface of the second redistribution substrate 400. The second molding layer 650 may cover the second semiconductor chip 600 and may surround the second conductive posts 530.

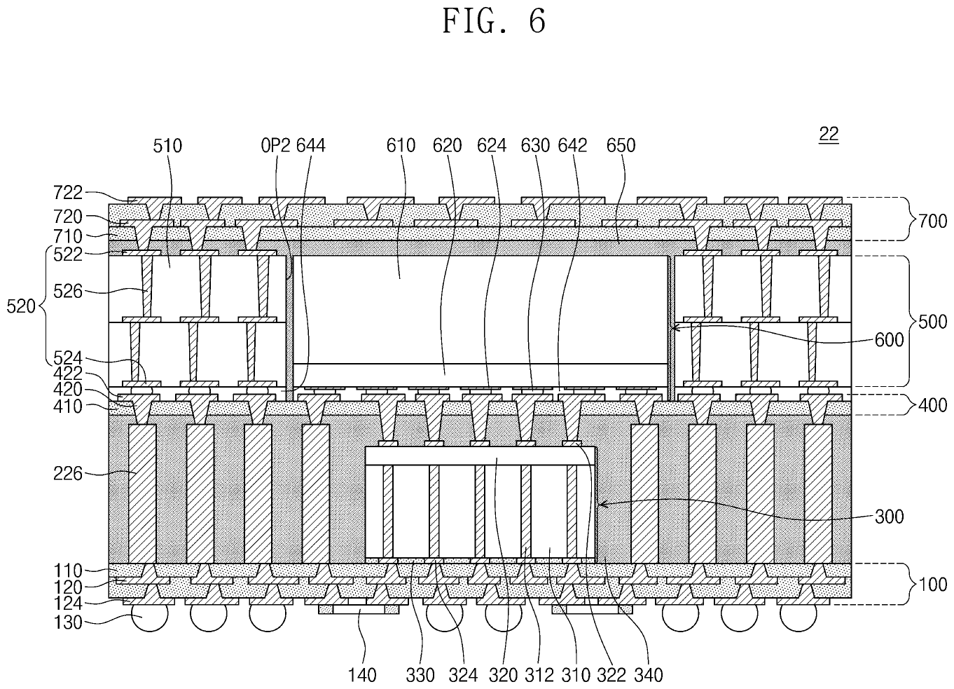

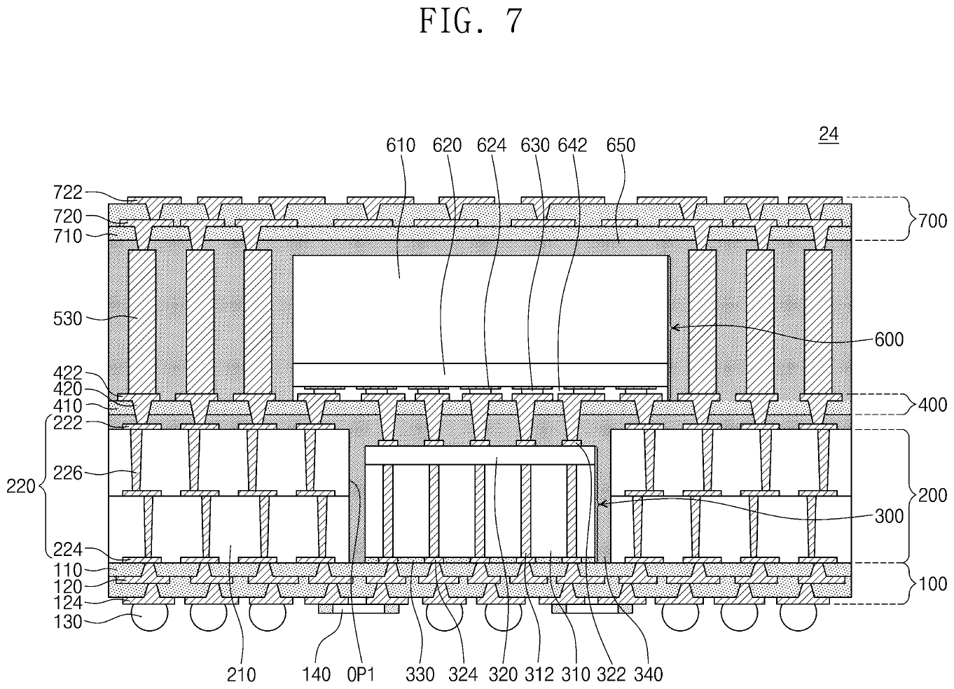

The second conductive posts 530 may be disposed on one side of the second semiconductor chip 600. The second conductive posts 530 may be disposed between an outer lateral surface of the second semiconductor chip 600 and an outer lateral surface of the second molding layer 650. The second conductive posts 530 may vertically penetrate the second molding layer 650. The second conductive posts 530 may have their ends that extend toward the top surface of the second redistribution substrate 400. The second conductive posts 530 may have their bottom surfaces exposed on a bottom surface of the second molding layer 650. The bottom surfaces of the second conductive posts 530 may be coplanar with the bottom surface of the second molding layer 650. The second conductive posts 530 may penetrate the second molding layer 650 to be coupled to the second substrate wiring pattern 420. The second conductive posts 530 may have their other ends that extend toward a bottom surface of the third redistribution substrate 700. The second conductive posts 530 may have their top surfaces exposed on a top surface of the second molding layer 650. The top surfaces of the second conductive posts 530 may be coplanar with the top surface of the second molding layer 650. The second conductive posts 530 may penetrate the second molding layer 650 to be coupled to the third substrate wiring pattern 720. For example, the second redistribution substrate 400 may be connected through the second conductive posts 530 to the third redistribution substrate 700. The second conductive posts 530 may be a vertical connection structure that connects the second redistribution substrate 400 to the third redistribution substrate 700. The second conductive posts 530 may include a conductive material, such as copper (Cu). In other embodiments, a second connection substrate 500 may be provided instead of the second conductive posts 530. According to some embodiments, as illustrated in FIG. 6, a semiconductor package 22 may be configured such that the first redistribution substrate 100 and the second redistribution substrate 400 are connected through the first conductive posts 230. The second redistribution substrate 400 may be connected through the second connection substrate 500 to the third redistribution substrate 700. The second connection substrate 500 may be substantially the same as or similar to the second connection substrate 500 discussed above with reference to FIG. 1. In other embodiments, a first connection substrate 200 may be provided instead of the first conductive posts 230. According to some embodiments, as illustrated in FIG. 7, a semiconductor package 24 may be configured such that the first redistribution substrate 100 is connected through the first connection substrate 200 to the second redistribution substrate 400. The second redistribution substrate 400 may be connected through the second conductive posts 530 to the third redistribution substrate 700. The first connection substrate 200 may be substantially the same as or similar to the first connection substrate 200 discussed above with reference to FIG. 1.

According to some embodiments of the present inventive concepts, the second conductive posts 530 and the second semiconductor chip 600 may be directly mounted on the top surface of the second redistribution substrate 400 that is directly coupled to the first conductive posts 230 and the first semiconductor chip 300. For example, no discrete redistribution substrate may be provided to connect the second conductive posts 530 to the second semiconductor chip 600. In addition, no solder balls may be separately provided to connect the discrete redistribution substrate to the second redistribution substrate 400. Therefore, the semiconductor packages may be provided to have a small size and improved structural stability. In addition, the first and second semiconductor chips 300 and 600 may be connected through the second substrate wiring pattern 420, and thus there may be a reduction in electrical length. Accordingly, the semiconductor packages may have improved electrical properties.

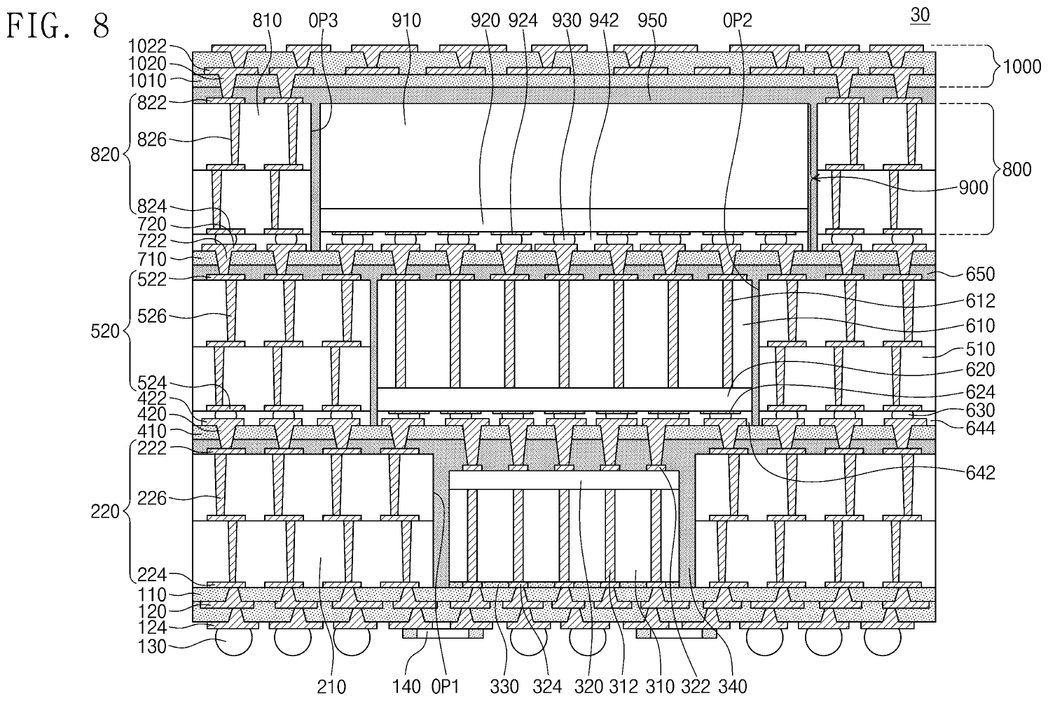

FIG. 8 illustrates a cross-sectional view showing a semiconductor package according to some embodiments of the present inventive concepts.

Referring back to FIG. 8, a third connection substrate 800 may be provided on the third redistribution substrate 700. The third connection substrate 800 may have a third opening OP3 that penetrates the third connection substrate 800. In addition, the third connection substrate 800 may include a third base layer 810 and a third conductive member 820 in the third base layer 810. The third conductive member 820 may include third upper pads 822, third lower pads 824, and third vias 826.

The third upper pads 822 may be disposed on a top surface of the third connection substrate 800. The third upper pads 822 may protrude onto the top surface of the third connection substrate 800. In other embodiments, the third upper pads 822 may be buried in an uppermost third base layer 810, and top surfaces of the third upper pads 822 in the uppermost third base layer 810 may be coplanar with the top surface of the third connection substrate 800. The third lower pads 824 may be disposed on a bottom surface of the third connection substrate 800. The third lower pads 824 may be buried in a lowermost third base layer 810, and bottom surfaces of the third lower pads 824 may be coplanar with the bottom surface of the third connection substrate 800. The third through vias 826 may penetrate the third base layer 810 to electrically connect the third upper pads 822 to the third lower pads 824.

FIG. 8 depicts that the third base layer 810 is separated into two layers, but the present inventive concepts are not limited thereto. The third base layer 810 may be separated into three or four layers.

A third semiconductor chip 900 may be disposed on the third redistribution substrate 700. The third semiconductor chip 900 may include a second semiconductor substrate 610 and a second circuit layer 620 provided on a bottom surface of the second semiconductor substrate 610. The third semiconductor chip 900 may be disposed in the third opening OP3 of the third connection substrate 800. In this case, the third semiconductor chip 900 may be disposed on the third redistribution substrate 700 exposed by the third opening OP3.

The third connection substrate 800 and the third semiconductor chip 900 may be mounted on the third redistribution substrate 700. For example, the third connection substrate 800 and the third semiconductor chip 900 may be coupled through third connection terminals 930 to the third pads 722. The third connection terminals 930 may be provided between the third pads 722 and fifth chip pads 924 on a bottom surface of the third semiconductor chip 900 and between the third pads 722 and the third lower pads 824. For example, the third connection substrate 800 and the third semiconductor chip 900 may be electrically connected through the third connection terminals 930 to the third redistribution substrate 700. As the third connection substrate 800 and the third semiconductor chip 900 are mounted through the third connection terminals 930 on the third redistribution substrate 700, the bottom surface of the third connection substrate 800 and the bottom surface of the third semiconductor chip 900 may be spaced apart from the third redistribution substrate 700. The third connection terminals 930 may include a solder ball or a solder bump.

A third underfill layer 942 may be provided between a top surface of the third redistribution substrate 700 and the bottom surface of the third semiconductor chip 900. The third underfill layer 942 may fill a space between the third redistribution substrate 700 and the third semiconductor chip 900, and may surround the third connection terminals 930 and the third pads 722.

A fourth underfill layer 944 may be provided between the top surface of the third redistribution substrate 700 and the bottom surface of the third connection substrate 800. The fourth underfill layer 944 may fill a space between the third redistribution substrate 700 and the third connection substrate 800, and may surround the third lower pads 824, the third connection terminals 930, and the third pads 722.

A third molding layer 950 may be provided on the third redistribution substrate 700. The third molding layer 950 may cover the third connection substrate 800 and the third semiconductor chip 900. The third molding layer 950 may fill a space between the third connection substrate 800 and the third semiconductor chip 900 and a space between the third underfill layer 942 and the fourth underfill layer 944. The third molding layer 950 may include a dielectric polymer material. For example, the third molding layer 950 may include an epoxy molding compound (EMC) or an epoxy dielectric film such as an Ajinomoto build-up film (ABF).

A fourth redistribution substrate 1000 may be provided on the third molding layer 950. The fourth redistribution substrate 1000 may include one fourth substrate wiring layer or at least two fourth substrate wiring layers that are stacked on each other. Each of the fourth substrate wiring layers may include a fourth substrate dielectric pattern 1010 and a fourth substrate wiring pattern 1020 in the fourth substrate dielectric pattern 1010. The fourth substrate wiring pattern 1020 provided on an uppermost fourth substrate wiring layer may be fourth pads 1022 to which is coupled an external apparatus mounted on the fourth redistribution substrate 1000.

The fourth substrate wiring pattern 1020 may have a damascene structure. For example, the fourth substrate wiring pattern 1020 may have a via that protrudes onto a bottom surface thereof. The via may be a component for vertically connecting to each other the fourth substrate wiring patterns 1020 of two neighboring ones of the fourth substrate wiring layers. The via may be a component for connecting the fourth substrate wiring pattern 1020 of the uppermost fourth substrate wiring layer to the third connection substrate 800. For example, the via may penetrate a lowermost fourth substrate dielectric pattern 101 and the third molding layer 950 to be coupled to the third upper pads 822 of the third connection substrate 800. In this configuration, a lower portion of the fourth substrate wiring pattern 1020 positioned on a top surface of the fourth substrate dielectric pattern 1010 may be a head part used as a horizontal line or pad, and the via of the fourth substrate wiring pattern 1020 may be a tail part. The fourth substrate wiring pattern 1020 may have a T shape, as illustrated in FIG. 8.

According to some embodiments of the present inventive concepts, the third connection substrate 800 and the third semiconductor chip 900 may be mounted on the top surface of the third redistribution substrate 700 directly coupled to the second connection substrate 500 and the second semiconductor chip 600. For example, no discrete redistribution substrate may be provided to connect the third connection substrate 800 to the third semiconductor chip 900. In addition, no solder balls may be separately provided to connect the discrete redistribution substrate to the third redistribution substrate 700. Therefore, a semiconductor package 30 may be provided to have a small size and improved structural stability.

In addition, the second and third connection substrates 500 and 800 and the second and third semiconductor chips 600 and 900 may be connected to each other through the third substrate wiring pattern 720, and thus there may be a reduction in electrical length. Accordingly, the semiconductor package 30 may have improved electrical properties.

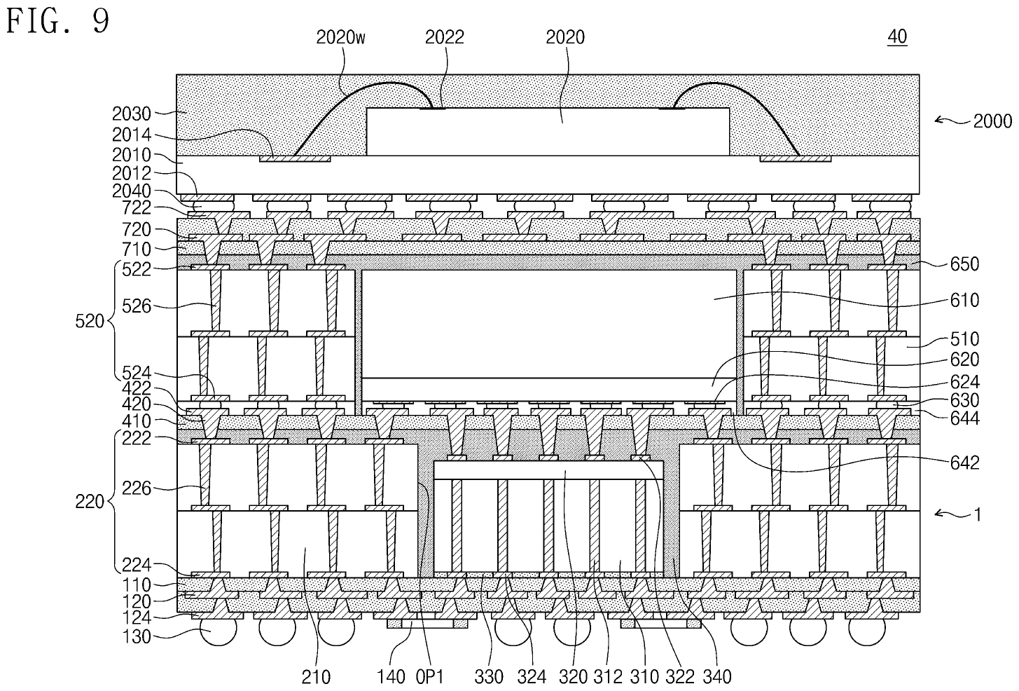

FIG. 9 illustrates a cross-sectional view showing a semiconductor package according to some embodiments of the present inventive concepts.

Referring to FIG. 9, a semiconductor package 40 may include a lower package 1 and an upper package 2000. For example, the semiconductor package 40 may be a package-on-package (POP) in which the upper package 2000 is mounted on the lower package 1.

The lower package 1 may be substantially the same as or similar to one of the semiconductor packages 10, 12, 20, 22, 24, and 30 discussed with reference to FIGS. 1 to 8. For example, the lower package 1 may include the first redistribution substrate 100, the first connection substrate 200, the first semiconductor chip 300, the first molding layer 340, the second redistribution substrate 400, the second connection substrate 500, the second semiconductor chip 600, the second molding layer 650, and the third redistribution substrate 700. In other embodiments, the lower package 1 may further include the third connection substrate 800, the third semiconductor chip 900, and the fourth redistribution substrate 1000. In other embodiments, the semiconductor package 40 may include first conductive posts 230 instead of the first connection substrate 200, and may also include second conductive posts 530 instead of the second connection substrate 500.

The upper package 2000 may be mounted on the lower package 1. The upper package 2000 may include an upper package substrate 2010, an upper package chip 2020, and an upper molding layer 2030.

The upper package substrate 2010 may be a printed circuit board (PCB). In some embodiments, the upper package substrate 2010 may be a redistribution substrate.

The upper package chip 2020 may be disposed on the upper package substrate 2010. The upper package chip 2020 may include integrated circuits, and the integrated circuits may include a memory circuit, a logic circuit, or a combination thereof. The upper package chip 2020 may be a semiconductor chip whose type is different from that of the first and second semiconductor chips 300 and 600. For example, the upper package chip 2020 may be a memory chip. The upper package chip 2020 may include upper chip pads 2022 electrically connected through bonding wires 2020w to sixth pads 2014 provided on a top surface of the upper package substrate 2010. FIG. 9 depicts that the upper package chip 2020 is mounted in a wire bonding manner, but the upper package chip 2020 may be mounted in various ways. In addition, FIG. 9 depicts that one upper package chip 2020 is mounted, but the present inventive concepts are not limited thereto. At least two package chips may be mounted on the upper package substrate 2010.

The upper package substrate 2010 may be provided thereon with the upper molding layer 2030 that covers the upper package chip 2020. The upper molding layer 2030 may include a dielectric polymer, such as an epoxy-based polymer.

The lower package 1 and the upper package 2000 may be provided with fourth connection terminals 2040 therebetween. The fourth connection terminals 2040 may be interposed between an uppermost third substrate wiring pattern 720 of the third redistribution substrate 700 and seventh pads 2012 provided on a bottom surface of the upper package substrate 2010, thereby being electrically connected to the third substrate wiring pattern 720 and the seventh pads 2012. Therefore, the upper package 2000 may be electrically connected to the first semiconductor chip 300, the second semiconductor chip 600, and the external terminals 130 through the fourth connection terminals 2040, the third redistribution substrate 700, the first connection substrate 200, the second connection substrate 500, and the first redistribution substrate 100.

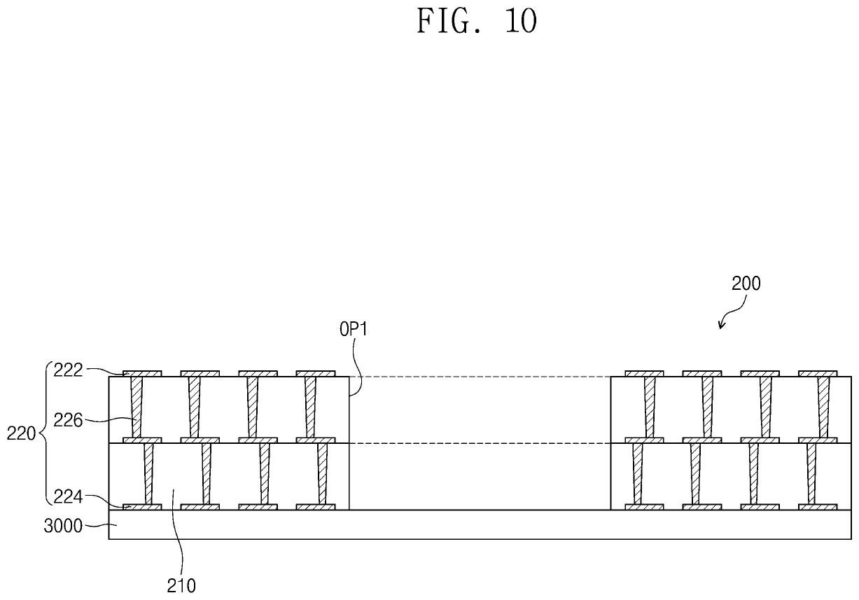

FIGS. 10 to 15 illustrate cross-sectional views showing a method of fabricating a semiconductor package according to some embodiments of the present inventive concepts.

Referring to FIG. 10, a first connection substrate 200 may be provided. The first connection substrate 200 may be substantially the same as or similar to the first connection substrate 200 discussed with reference to FIG. 1. For example, the first connection substrate 200 may include a first base layer 210 and a first conductive member 220. The first conductive member 220 may include first upper pads 222, first lower pads 224, and first vias 226.

A first carrier substrate 3000 may be attached to a bottom surface of the first connection substrate 200. The first carrier substrate 3000 may be a dielectric substrate including glass or polymer, or may be a conductive substrate including metal. Although not shown, the first carrier substrate 3000 may be attached through a first adhesive member provided on a top surface thereof to a lowermost first base layer 210 and the first lower pads 224.

A first opening OP1 may be formed in the first connection substrate 200. A portion of the first connection substrate 200 may be removed to form the first opening OP1 that penetrates the first connection substrate 200. For example, the first opening OP1 may be formed by performing an etching process, such as drilling, laser ablation, or laser cutting. The removed portion of the first connection substrate 200 may be a space in which a first semiconductor chip 300 is provided in a subsequent process.

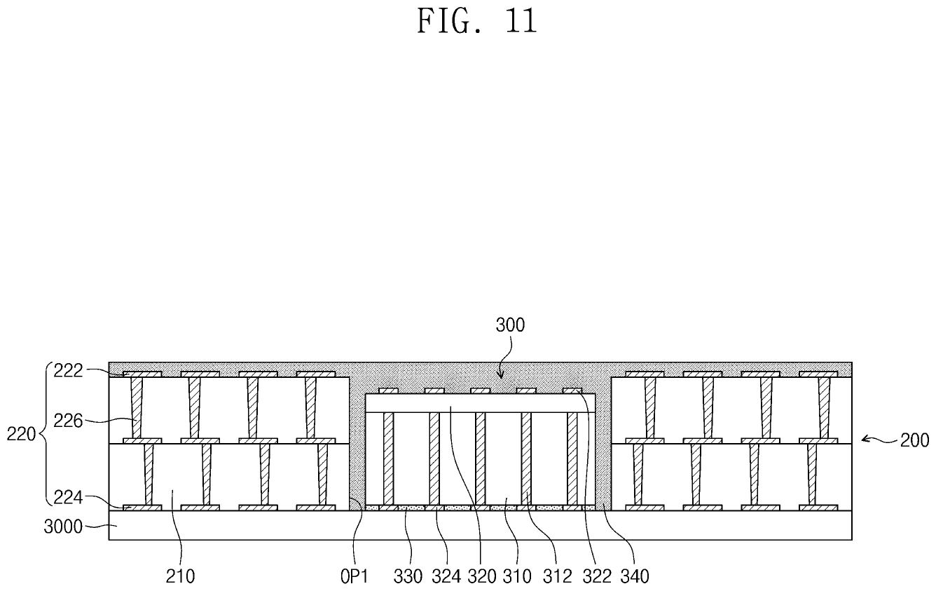

Referring to FIG. 11, a first semiconductor chip 300 may be provided on the first carrier substrate 3000. The first semiconductor chip 300 may be substantially the same as or similar to the first semiconductor chip 300 discussed above with reference to FIG. 1. The first semiconductor chip 300 may be disposed in the first opening OP1 of the first connection substrate 200. The first semiconductor chip 300 may be attached to the first carrier substrate 3000. In this case, a rear surface of the first semiconductor chip 300 may be attached to the first carrier substrate 3000.

A first molding layer 340 may be formed on the first carrier substrate 3000. The first molding layer 340 may fill a space between the first connection substrate 200 and the first semiconductor chip 300. For example, a dielectric member may be injected between the first connection substrate 200 and the first semiconductor chip 300, and then the dielectric member may be cured to form the first molding layer 340. The first molding layer 340 may be formed to cover the first connection substrate 200 and the first semiconductor chip 300. Therefore, the first upper pads 222 of the first connection substrate 200 may not be exposed, and first chip pads 322 of the first semiconductor chip 300 may not be exposed.

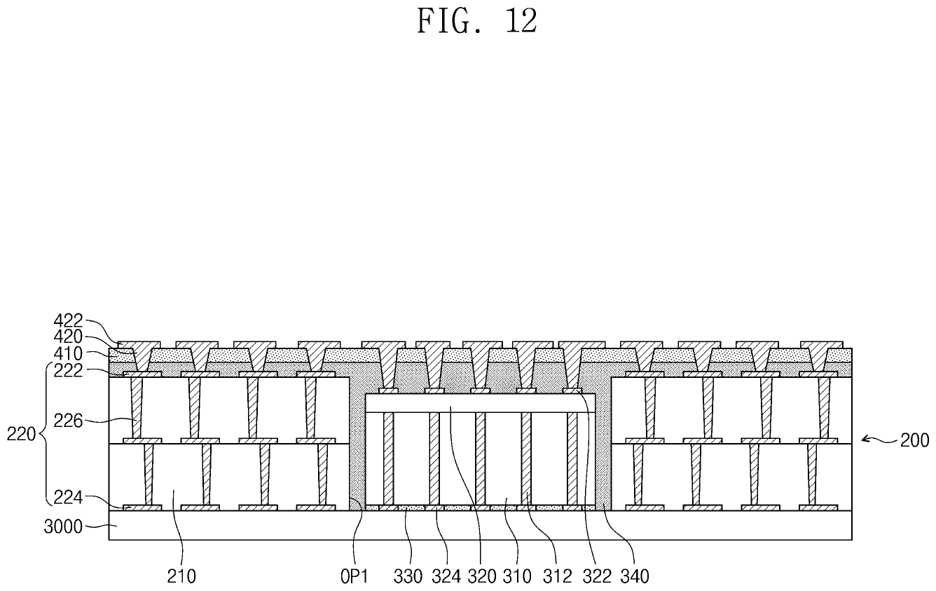

Referring to FIG. 12, a second redistribution substrate 400 may be formed on the first molding layer 340. For example, a dielectric layer may be formed on the first molding layer 340, and the dielectric layer may be patterned to form one second substrate dielectric pattern 410. The dielectric layer may undergo an etching process that uses a laser such that a portion of the dielectric layer and a portion of the first molding layer 340 may be removed to form through holes that partially expose top surfaces of the first upper pads 222 and top surfaces of the first chip pads 322. The through holes may be filled with a conductive material to form a conductive layer on the second substrate dielectric pattern 410, and the conductive layer may be patterned to form a second substrate wiring pattern 420. It may thus be possible to form the second redistribution substrate 400 having one second substrate wiring layer. FIG. 11 depicts that one second substrate wiring layer is formed, but the present inventive concepts are not limited thereto. Afterwards, the formation of the second substrate dielectric pattern 410 and the second substrate wiring pattern 420 may be repeatedly performed to form the second redistribution substrate 400 having a plurality of second substrate wiring layers. Second pads 422 may be defined to indicate the second substrate wiring pattern 420 provided on an uppermost second substrate wiring layer.

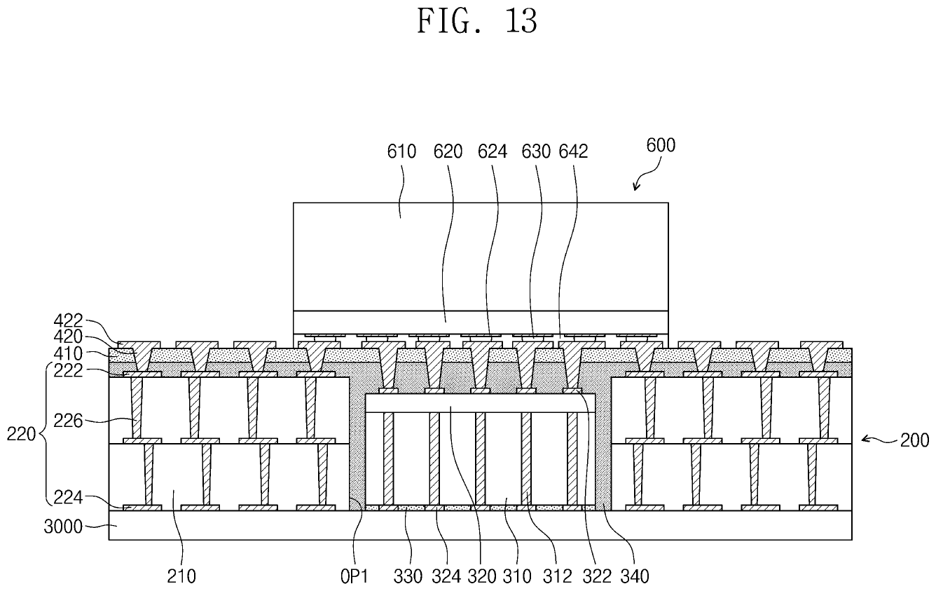

Referring to FIG. 13, a second semiconductor chip 600 may be provided on a resultant structure of FIG. 12. The second semiconductor chip 600 may be substantially the same as or similar to the second semiconductor chip 600 discussed above with reference to FIG. 1.

The second semiconductor chip 600 may be mounted on the second redistribution substrate 400. For example, solder balls may be provided on third chip pads 624 of the second semiconductor chip 600. The third chip pads 624 may be aligned with a portion of the second substrate wiring pattern 420. After that, the second semiconductor chips 600 may descend to allow the solder balls to contact the portion of the second substrate wiring pattern 420, and then the solder balls may undergo a reflow process to form first connection terminals 630 that connect the second semiconductor chip 600 to the second redistribution substrate 400. Thereafter, between the second semiconductor chip 600 and the second redistribution substrate 400, a first underfill layer 642 may be formed to surround the third chip pads 624, the first connection terminals 630 attached to the third chip pads 624, and the second pads 422 attached to the first connection terminals 630.

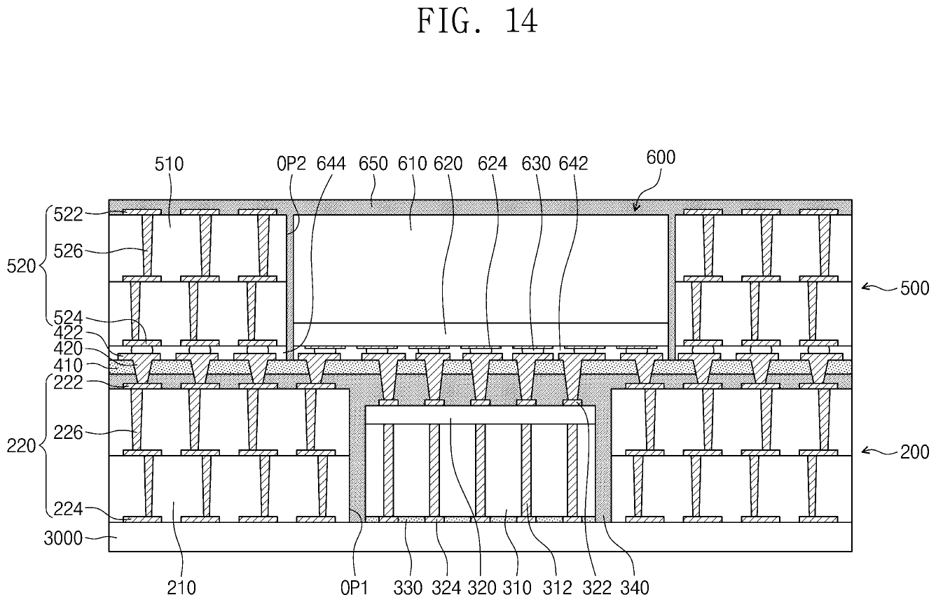

Referring to FIG. 14, a second connection substrate 500 may be provided on the second redistribution substrate 400. The second connection substrate 500 may be substantially the same as or similar to the second connection substrate 500 discussed above with reference to FIG. 1. For example, an etching process, such as drilling, laser ablation, or laser cutting, may be employed to remove a portion of the second connection substrate 500 to form a second opening OP2 that penetrates the second connection substrate 500. The removed portion of the second connection substrate 500 may be a space in which a second semiconductor chip 600 is provided in a subsequent process.

The second connection substrate 500 may be mounted on the second redistribution substrate 400. For example, solder balls may be provided on second lower pads 524 of the second connection substrate 500. The second lower pads 524 may be aligned with a remaining portion of the second substrate wiring pattern 420 of the second redistribution substrate 400. For example, the second connection substrate 500 may be positioned on the second redistribution substrate 400 to allow the second semiconductor chip 600 to reside in the second opening OP2 of the second connection substrate 500. After that, the second connection substrate 500 may descend to allow the solder balls to contact the remaining portion of the second substrate wiring pattern 420, and then the solder balls may undergo a reflow process to form first connection terminals 630 that connect the second connection substrate 500 to the second redistribution substrate 400. Thereafter, between the second connection substrate 500 and the second redistribution substrate 400, a second underfill layer 644 may be formed to surround the second lower pads 524, the first connection terminals 630 attached to the second lower pads 524, and the second pads 422 attached to the first connection terminals 630. In other embodiments, the process sequence in accordance with FIGS. 13 and 14 may be reversed. For example, the second connection substrate 500 may be mounted on the second redistribution substrate 400, and then the second semiconductor chip 600 may be mounted in the second opening OP2. According to some embodiments of the present inventive concepts, a third connection substrate 800 and the second semiconductor chip 600 may be mounted on a top surface of the second redistribution substrate 400 directly coupled to the first connection substrate 200 and the first semiconductor chip 300. For example, no discrete redistribution substrate may be provided to connect the third connection substrate 800 to the second semiconductor chip 600. In addition, no solder balls may be separately provided to connect the discrete redistribution substrate to the second redistribution substrate 400. Therefore, a semiconductor package may be provided to have a small size and improved structural stability. The following description will be disclosed continuously with reference to FIG. 14.

A second molding layer 650 may be formed on the second redistribution substrate 400. For example, on the top surface of the second redistribution substrate 400, a dielectric material may be coated to cover a top surface of the second connection substrate 500 and a top surface of the second semiconductor chip 600 and to surround the first and second underfill layers 642 and 644, and then the dielectric material may be cured to form the second molding layer 650.

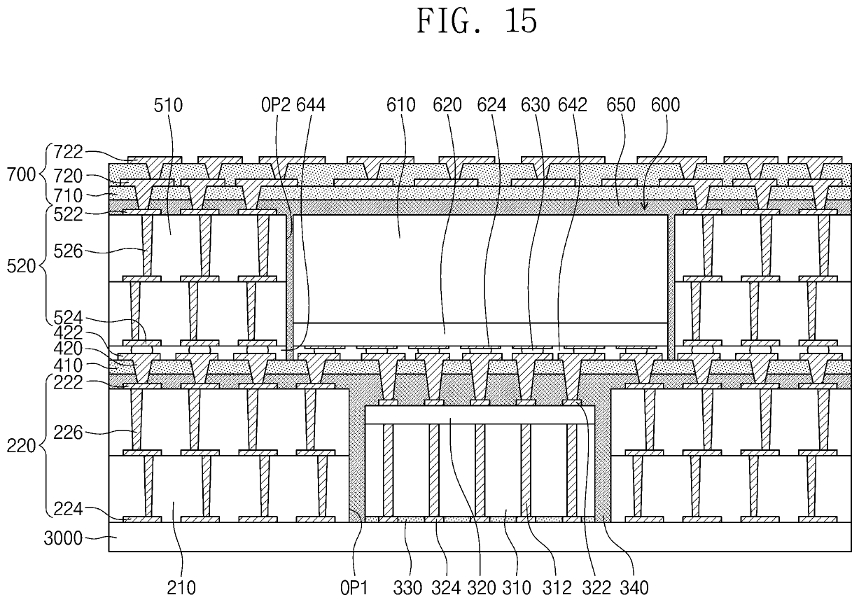

Referring to FIG. 15, a third redistribution substrate 700 may be formed on the second molding layer 650. For example, a dielectric layer may be formed on the second molding layer 650, and the dielectric layer may be patterned to form one third substrate dielectric pattern 710. The dielectric layer may undergo an etching process that uses a laser such that a portion of the dielectric layer and a portion of the second molding layer 650 may be removed to form through holes that partially expose the top surfaces of second upper pads 522. According to some embodiments, the dielectric layer and the second molding layer 650 may be partially removed to form the through holes that partially expose the top surfaces of the second upper pads 522 and top surfaces of fourth chip pads 622 provided on the top surface of the second semiconductor chip 600. The following description will be disclosed continuously with reference to FIG. 15. The through holes may be filled with a conductive material to form a conductive layer on the third substrate dielectric pattern 710, and the conductive layer may be patterned to form a third substrate wiring pattern 720. Afterwards, the formation of the third substrate dielectric pattern 710 and the third substrate wiring pattern 720 may be repeatedly performed to form the third redistribution substrate 700 having a plurality of third substrate wiring layers. Third pads 722 may be defined to indicate the third substrate wiring pattern 720 provided on an uppermost third substrate wiring layer.

Referring back to FIG. 1, the first carrier substrate 3000 may be removed, and then a first redistribution substrate 100 may be formed on a bottom surface of the first connection substrate 200, a bottom surface of the first semiconductor chip 300, and a bottom surface of the first molding layer 340. For example, a dielectric layer may be formed on the bottom surface of the first connection substrate 200, the bottom surface of the first semiconductor chip 300, and the bottom surface of the first molding layer 340, and the dielectric layer may be patterned to form a first substrate dielectric pattern 110. A conductive layer may be formed on the first substrate dielectric pattern 110, and the conductive layer may be patterned to form a first substrate wiring pattern 120. After that, the formation of the first substrate dielectric pattern 110 and the first substrate wiring pattern 120 may be repeatedly performed to form the first redistribution substrate 100 having a plurality of first substrate wiring layers. First pads 124 may be defined to indicate the first substrate wiring pattern 120 provided on a lowermost first substrate wiring layer. Some of the first pads 124 may undergo a solder ball process to form external terminals 130, and passive elements 140 may be attached to remaining others of the first pads 124. Through the method discussed above, a semiconductor package 10 may be formed.

In a semiconductor package according to some embodiments of the present inventive concepts, an upper semiconductor chip and an upper connection substrate may be directly mounted on a top surface of a redistribution substrate directly coupled to a lower semiconductor chip and a lower connection substrate. Therefore, no discrete redistribution substrate may be provided to connect the upper semiconductor chip to the upper connection substrate, and no solder balls may be provided between the discrete redistribution substrate and the redistribution substrate. Accordingly, the semiconductor package may have a small size and improved structural stability.

In addition, the lower semiconductor chip and the lower connection substrate may be connected through one redistribution substrate to the upper semiconductor chip and the upper connection substrate, and thus a reduced electrical length may be provided therebetween. Accordingly, the semiconductor package may have improved electrical properties.

According to some embodiments of the present inventive concepts, vias that penetrate a semiconductor chip may be used to achieve a reduced electrical length between redistribution substrate provided between upper and lower sides of the semiconductor chip. Accordingly, the semiconductor package may have improved electrical properties.

What is claimed is:

1. A semiconductor package, comprising:
a first redistribution substrate;
a first semiconductor chip on a top surface of the first redistribution substrate, wherein the first semiconductor chip comprises a plurality of first pads on a top surface of the first semiconductor chip;
a second redistribution substrate on the top surface of the first semiconductor chip;
a first vertical connection structure adjacent one side of the first semiconductor chip, wherein the first redistribution substrate and the second redistribution substrate are electrically connected to each other by the first vertical connection structure;
a second semiconductor chip on a top surface of the second redistribution substrate;
a first molding layer on the second semiconductor chip;
a third redistribution substrate on a top surface of the first molding layer; and
a second vertical connection structure on the top surface of the second redistribution substrate and adjacent one side of the second semiconductor chip, wherein the second redistribution substrate and the third redistribution substrate are electrically connected to each other by the second vertical connection structure,
wherein a wiring pattern of the second redistribution substrate is coupled to the plurality of first pads of the first semiconductor chip.

2. The semiconductor package of claim 1, further comprising a second molding layer on the first semiconductor chip,
wherein the wiring pattern of the second redistribution substrate penetrates the second molding layer and is coupled to the plurality of first pads.

3. The semiconductor package of claim 2, wherein
the first vertical connection structure comprises a first connection substrate that connects the first redistribution substrate to the second redistribution substrate,
the first connection substrate has a first opening in the first connection substrate,
the first semiconductor chip is in the first opening, and
the second molding layer is in a space between the first connection substrate and the first semiconductor chip.

4. The semiconductor package of claim 2, wherein the first vertical connection structure comprises a plurality of first conductive posts that penetrate the second molding layer to connect the first redistribution substrate to the second redistribution substrate.

5. The semiconductor package of claim 1, wherein
a bottom surface of the first semiconductor chip is in direct contact with the top surface of the first redistribution substrate, and
a wiring pattern of the first redistribution substrate is directly coupled to a plurality of second pads on the bottom surface of the first semiconductor chip.

6. The semiconductor package of claim 1, further comprising a plurality of first connection terminals between the first semiconductor chip and the first redistribution substrate,
wherein the first semiconductor chip is connected to the first redistribution substrate by the plurality of first connection terminals.

7. The semiconductor package of claim 1, wherein
the second vertical connection structure comprises a second connection substrate that connects the second redistribution substrate to the third redistribution substrate,
the second connection substrate has a second opening in the second connection substrate,
the second semiconductor chip is in the second opening, and
the first molding layer is in a space between the second connection substrate and the second semiconductor chip.

8. The semiconductor package of claim 1, wherein the second vertical connection structure comprises a plurality of second conductive posts that penetrate the first molding layer to connect the second redistribution substrate to the third redistribution substrate.

9. The semiconductor package of claim 1, wherein the first semiconductor chip further comprises:
a plurality of first through vias that penetrate the first semiconductor chip and are exposed on a bottom surface of the first semiconductor chip; and
a plurality of second pads on the bottom surface of the first semiconductor chip,
wherein a wiring pattern of the first redistribution substrate is coupled through the plurality of second pads to the plurality of first through vias.

10. The semiconductor package of claim 1, wherein the second semiconductor chip further comprises:
a plurality of second through vias that penetrate the second semiconductor chip and that are exposed on a top surface of the second semiconductor chip; and
a plurality of third pads on the top surface of the second semiconductor chip,
wherein a wiring pattern of the third redistribution substrate is coupled through the plurality of third pads to the plurality of second through vias.

11. The semiconductor package of claim 1, further comprising a plurality of second connection terminals between the second semiconductor chip and the second redistribution substrate,
wherein the second semiconductor chip is connected to the second redistribution substrate by the plurality of second connection terminals.

12. The semiconductor package of claim 1, wherein
the first semiconductor chip is arranged such that an active surface of the first semiconductor chip faces a bottom surface of the third redistribution substrate, and
the second semiconductor chip is arranged such that an active surface of the second semiconductor chip faces the top surface of the first redistribution substrate.

13. The semiconductor package of claim 1, wherein a width of the second semiconductor chip is greater than a width of the first semiconductor chip.

14. The semiconductor package of claim 1, further comprising an upper package on a top surface of the third redistribution substrate.

15. A semiconductor package, comprising:
a first redistribution substrate;
a second redistribution substrate on the first redistribution substrate;
a first connection substrate between the first redistribution substrate and the second redistribution substrate, wherein the first connection substrate comprises a first opening in the first connection substrate and a plurality of first pads on a top surface of the first connection substrate;
a first semiconductor chip in the first opening between the first redistribution substrate and the second redistribution substrate, wherein the first semiconductor chip comprises a plurality of first through vias that penetrate the first semiconductor chip;
a first molding layer between the first redistribution substrate and the second redistribution substrate, wherein the first molding layer is on the first semiconductor chip and the first connection substrate and is in a space between the first semiconductor chip and the first connection substrate;
a third redistribution substrate on the second redistribution substrate;
a second connection substrate between the second redistribution substrate and the third redistribution substrate, wherein the second connection substrate comprises a second opening in the second connection substrate and a plurality of second pads on a top surface of the second connection substrate; and
a second semiconductor chip in the second opening between the second redistribution substrate and the third redistribution substrate,
wherein the second semiconductor chip and the second connection substrate are connected to a top surface of the second redistribution substrate by a plurality of first connection terminals between the second semiconductor chip and the second redistribution substrate and between the second connection substrate and the second redistribution substrate, and
wherein a wiring pattern of the second redistribution substrate penetrates the first molding layer and is coupled to the plurality of first pads.

16. The semiconductor package of claim 15, further comprising a second molding layer on the second redistribution substrate, wherein the second molding layer is on the second semiconductor chip and the second connection substrate and is in a space between the second semiconductor chip and the second connection substrate,
wherein a wiring pattern of the third redistribution substrate penetrates the second molding layer and is coupled to the plurality of second pads.

17. The semiconductor package of claim 16, further comprising:
a fourth redistribution substrate on the third redistribution substrate;
a third connection substrate between the third redistribution substrate and the fourth redistribution substrate, wherein the third connection substrate comprises a third opening in the third connection substrate and a plurality of third pads on a top surface of the third connection substrate;
a third semiconductor chip in the third opening between the third redistribution substrate and the fourth redistribution substrate; and
a third molding layer between the third redistribution substrate and the fourth redistribution substrate, wherein the third molding layer is on the third semiconductor chip and the third connection substrate and is in a space between the third semiconductor chip and the third connection substrate,
wherein the third semiconductor chip and the third connection substrate are connected to a top surface of the third redistribution substrate by a plurality of second connection terminals between the third semiconductor chip and the third redistribution substrate and between the third connection substrate and the third redistribution substrate, and
wherein a wiring pattern of the fourth redistribution substrate penetrates the third molding layer and is coupled to the plurality of third pads.

18. The semiconductor package of claim 17, wherein the second semiconductor chip further comprises:
a plurality of second through vias that penetrate the second semiconductor chip and are exposed on a top surface of the second semiconductor chip; and
a plurality of fourth pads on the top surface of the second semiconductor chip,
wherein the wiring pattern of the third redistribution substrate is coupled to the plurality of second through vias by the plurality of fourth pads.

19. A semiconductor package, comprising:
a lower package; and
an upper package on the lower package,
wherein the lower package comprises:
a first redistribution substrate;
a first connection substrate on a top surface of the first redistribution substrate, wherein the first connection substrate comprises a first opening in the first connection substrate;
a first semiconductor chip in the first opening and on the top surface of the first redistribution substrate, wherein the first semiconductor chip comprises a plurality of first pads on a top surface of the first semiconductor chip;
a plurality of external terminals on a bottom surface of the first redistribution substrate;
a second redistribution substrate on the first connection substrate and the first semiconductor chip;
a second connection substrate on a top surface of the second redistribution substrate, wherein the second connection substrate comprises a second opening in the second connection substrate;
a second semiconductor chip in the second opening and on the top surface of the second redistribution substrate; and
a third redistribution substrate on the second redistribution substrate,
wherein the upper package comprises:
an upper package substrate; and
an upper package chip on the upper package substrate,
wherein a wiring pattern of the second redistribution substrate is coupled to the plurality of first pads of the first semiconductor chip.

20. The semiconductor package of claim 19, further comprising:
a first molding layer between the first redistribution substrate and the second redistribution substrate, wherein the first molding layer is on the first semiconductor chip and the first connection substrate and is in a space between the first semiconductor chip and the first connection substrate; and
a second molding layer between the second redistribution substrate and the third redistribution substrate, wherein the second molding layer is on the second semiconductor chip and the second connection substrate and is in a space between the second semiconductor chip and the second connection substrate,
wherein the wiring pattern of the second redistribution substrate penetrates the first molding layer to connect the first connection substrate to the first semiconductor chip.
